(19) United States
(12) Patent Application Publication
(10) Pub. No.: US 2021/0405769 A1
(43) Pub. Date: Dec. 30, 2021

(54) APPARATUS AND METHOD FOR PROCESSING ROTOR MOVEMENT INFORMATION, AND ELECTRONIC DEVICE

(71) Applicant: SAMSUNG ELECTRO-MECHANICS CO., LTD., Suwon-si (KR)

(72) Inventors: Yong Wook KIM, Suwon-si (KR); Si Young KWON, Suwon-si (KR)

(73) Assignee: SAMSUNG ELECTRO-MECHANICS CO., LTD., Suwon-si (KR)

(21) Appl. No.: 17/036,175

(22) Filed: Sep. 29, 2020

(30) Foreign Application Priority Data
Jun. 25, 2020 (KR) 10-2020-0077612

(51) Int. Cl. G06F 3/038; G06F 3/0362; G06F 3/041

(52) U.S. Cl. CPC G06F 3/038; G06F 3/041; G06F 3/0362

(57) ABSTRACT

An apparatus for processing rotor movement information includes a processor configured to: receive movement information of a rotor disposed on one surface of an electronic device and having a rotation axis formed in a direction of the electronic device; receive touch information of a sensor configured to sense a touch on another surface of the electronic device; and produce operating information of the electronic device based on the movement information of the rotor. The operating information of the electronic device has variable correlation of the operating information to the movement information, in accordance with the touch information.

### CROSS-REFERENCE TO RELATED APPLICATIONS

This application claims the benefit under 35 U.S.C. § 119(a) of Korean Patent Application No. 10-2020-0077612 filed on Jun. 25, 2020 in the Korean Intellectual Property Office, the entire disclosure of which is incorporated herein by reference for all purposes.

### BACKGROUND

### 1. Field

The following description relates to an apparatus and a method for processing movement information of a rotor, and an electronic device including an apparatus for processing movement information of a rotor.

### 2. Description of Related Art

Recently, types and designs of electronic devices have been diversified. In addition, a variety of user demands for electronic devices is gradually increasing, and accordingly, requirements for functions and designs of electronic devices are gradually increasing. In this regard, an electronic device may be provided with a rotor to satisfy the various demands of users based on various movements and designs of the rotor.

An electronic device including a rotor may cause a malfunction due to unintended force being applied to the rotor, and such a malfunction may deteriorate reliability of the electronic device for users.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an apparatus for processing rotor movement information includes a processor configured to: receive movement information of a rotor disposed on one surface of an electronic device and having a rotation axis formed in a direction of the electronic device; receive touch information of a sensor configured to sense a touch on another surface of the electronic device; and produce operating information of the electronic device based on the movement information of the rotor. The operating information of the electronic device has variable correlation of the operating information to the movement information, in accordance with the touch information.

The electronic device may be configured to output display information on a display surface. The one surface and the other surface of the electronic device may have a normal line different from a normal line of the display surface.

A portion of the display information may be based on the operating information.

The processor may be further configured to deliver the portion of the display information to a display member of the electronic device.

The movement information may include rotation angle information of the rotor and rotation axis translational motion information of the rotor. The processor may be further configured to produce the operating information based on the rotation axis translational motion information.

The processor may be further configured to receive the rotation axis translational motion information based on a switch configured to determine whether the switch contacts the rotor depending on rotation axis translational motion of the rotor.

The processor may be further configured to receive the rotation angle information based on a sensing coil configured to vary inductance in accordance with a rotation angle of the rotor.

The processor may be further configured to receive the touch information based on an inductor disposed to vary inductance in accordance with a distance between the sensor and the other surface of the electronic device.

The processor may be further configured to produce the operating information to vary correlation of the operating information to the movement information depending on whether the touch is held on the other surface of the electronic device.

In another general aspect, a method for processing rotor movement information includes: receiving movement information of a rotor disposed on one surface of an electronic device and having a rotation axis formed in a direction of the electronic device, and touch information of a sensor configured to sense a touch on another surface of the electronic device; selectively activating the movement information depending on the touch information; and producing operating information of the electronic device based on the movement information, in accordance with the selectively activating of the movement information.

The method may further include producing display information based on the operating information.

The method may further include delivering the display information to a display member. The display member may be configured to output the display information on a display surface having a normal line different from a normal line of the one surface and the other surface of the electronic device.

The movement information may include rotation angle information of the rotor and rotation axis translational motion information of the rotor. The producing of the electronic movement information may include producing the operating information based on the rotation axis translational motion information while the movement information is activated.

In another general aspect, an electronic device includes: a main body; a rotor disposed on one surface of the main body and having a rotation axis formed in a direction of the electronic device; and a sensor configured to sense a touch on another surface of the main body. The main body is configured to output the display information on a display surface based on movement information of the rotor, such that correlation of the display information to the movement information varies depending on whether a touch is sensed on the other surface of the main body.

The main body may be configured to output first display information, among the display information, based on a rotation angle of the rotor and second display information, among the display information, based on rotation axis translational motion of the rotor.

One portion of the rotor may protrude from the one surface of the electronic device, and another portion of the rotor may be inserted inward from the one surface of the electronic device.

The main body may include a switch configured to determine whether the switch contacts the rotor in accordance with rotation axis translational motion of the rotor.

The apparatus may further include a strap connected to the main body, wherein the strap is more flexible than the main body.

The main body may be further configured to output the display information based on the movement information of the rotor, such that correlation of the display information to the movement information varies depending on whether a touch is held on the other surface of the main body.

Other features and aspects will be apparent from the following detailed description, the drawings, and the claims.

### BRIEF DESCRIPTION OF DRAWINGS

FIG. 1A is a diagram illustrating an apparatus for processing rotor movement information and an electronic device, according to an embodiment.

FIG. 1B is a diagram illustrating a first state of an apparatus for processing rotor movement information and an electronic device, according to an embodiment.

FIG. 1C is a diagram illustrating a second state of an apparatus for processing rotor movement information and an electronic device, according to an embodiment.

FIGS. 2A and 2B are diagrams illustrating a wearable structure of an apparatus for processing rotor movement information and an electronic device, according to an embodiment.

FIG. 3A is a flow chart of a method for processing movement information of a rotor, according to an embodiment.

FIG. 3B is a flow chart illustrating a display linkage process of a method for processing movement information of a rotor, according to an embodiment.

FIG. 3C is a flow chart illustrating a selective application process of rotor motion information of a method for processing movement information of a rotor, according to an embodiment.

FIG. 4 is a diagram illustrating a sensor of an apparatus for processing rotor movement information and an electronic device, according to an embodiment.

FIGS. 5A and 5B are diagrams illustrating detailed structures of rotors that may be included in an apparatus for processing rotor movement information and an electronic device, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an embodiment or example, e.g., as to what an embodiment or example may include or implement, means that at least one embodiment or example exists in which such a feature is included or implemented while all examples and examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after gaining an understanding of the disclosure of this application. Further, although the examples described herein have a variety of configurations, other configurations are possible as will be apparent after an understanding of the disclosure of this application.

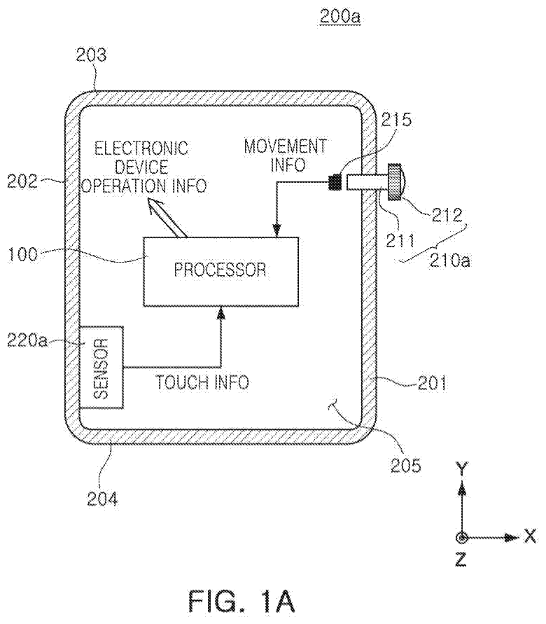

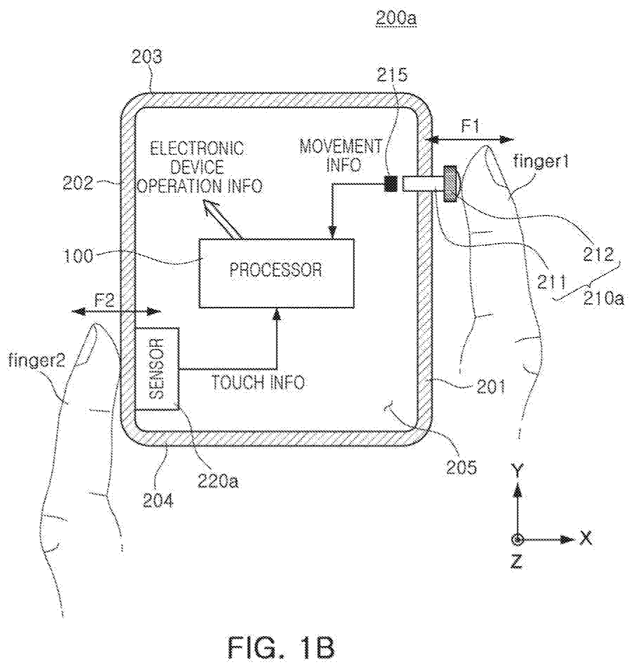

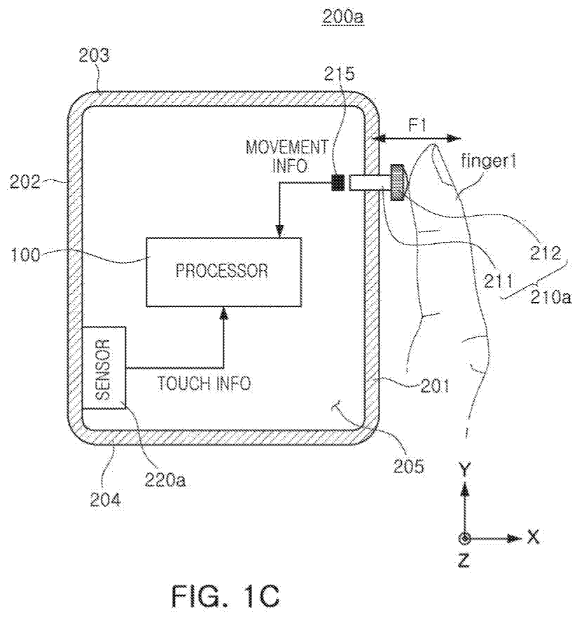

FIG. 1A is a diagram illustrating an apparatus for processing rotor movement information and an electronic device 200a, according to an example embodiment of the present disclosure.

Referring to FIG. 1A, the apparatus for processing rotor movement information may include, for example, a processor 100, and the electronic device 200a may include, for example, a main body including at least two of a first surface 201, a second surface 202, a third surface 203 and a fourth surface 204. The processor 100 may be disposed in an internal space 205 of the main body.

For example, the electronic device 200a may include a smart watch, a smart phone, a personal digital assistant, a digital video camera, a digital still camera, a network system, a computer, a monitor, a tablet, a laptop, a netbook, a television, a video game, an automotive, and the like, but is not limited to such examples.

The electronic device 200a may include the processor 100 and a storage element, such as a memory or a storage, configured to store information, as well as a communication element, such as a communication modem or an antenna, configured to remotely transmit and receive the information.

For example, the processor 100 may include a central processing unit (CPU), a graphics processing unit (GPU), a microprocessor, an application specific integrated circuit (ASIC), a field programmable gate array (FPGA), and the like, and may include a plurality of cores. The processor 100 may input and output information for the storage element and the communication element.

The processor 100 is disposed on the first surface 201 of the electronic device 200a and may receive movement information of a rotor 210a. A direction in which the rotor 210a extends toward the electronic device 200a (e.g., a −x direction) is a direction of a rotation axis.

For example, the rotor 210a may be a crown of a watch or a clock.

For example, the movement information of the rotor 210a may include any one or any combination of any two or more of rotation angle information, rotation axis translational motion information and rotation axis vertical motion information.

For example, the rotation angle information may include first, second, third, fourth, fifth, sixth, seventh and eighth rotation angle values respectively corresponding to states of rotation of 0°, 45°, 90°, 135°, 180°, 225°, 270° and 315°. The first rotation angle value may correspond to a still state of the rotor 210a, while the second to eighth rotation angle values may correspond to states in which the rotor 210a has moved from the still state.

For example, the rotation axis translational motion information may include a first rotation axis translational motion value corresponding to a state in which the rotor 210a has moved in a direction of the rotation axis (e.g., −x direction) and a second rotation axis translational motion value corresponding to a state in which the rotor 210a has not moved in the direction of the rotation axis.

For example, whether the rotor 210a has moved may correspond to whether a switch is in contact with the rotor 210a and also to whether a distance moved by the rotor 210a exceeds a reference distance.

For example, the rotation axis vertical motion information of the rotor 210a may correspond to whether a head 212 of the rotor 210a, as compared to a body 211 thereof, is positioned to be biased in a vertical direction (e.g., y direction) with respect to the rotation axis. In this case, a state in which movement values of the body 211 and the head 212 in a y-direction coordinate is smaller than a reference value may correspond to a state in which the rotor 210a is still in the y-direction, and a state in which movement values of the body 211 and the head 212 in a y-direction coordinate is greater than the reference value may correspond to a state in which the rotor 210a has moved in the y-direction.

The processor 100 may receive various movement information according to at least one combination of the rotation angle information, the rotation axis translational motion information and the rotation axis vertical motion information and may produce various electronic device operating information based on the movement information of the rotor 210a. For example, the main body of the electronic device 200a may output first display information based on a rotation angle of the rotor 210a and second display information based on rotation axis translational motion of the rotor 210a.

A structure advantageous in obtaining various types of movement information of the rotor 210a may be provided. However, such a structure may increase a likelihood of malfunctioning of the rotor 210a or unintended user operation of the rotor 210a.

The processor 100 may receive the touch information of a sensor 220a sensing a touch on at least one of the second to fourth surfaces 202 to 204.

Generally, when an external force (a force inducing a malfunction) irrelevant to a user is applied to the rotor 210a, the external force is not applied to at least one of the second to fourth surfaces 202 to 204, different from the first surface 201 on which the rotor 210a is disposed.

The electronic device 200a and the processor 100 may process information such that correlation between the electronic device movement information and the movement information (or display information) of the rotor 210a varies depending on a touch of the sensor 220a.

Accordingly, a frequency of occurrence of unintended electronic operating information of the processor 100 due to malfunctioning of the rotor 210a may be reduced, and a frequency of occurrence of unintended display information of the electronic device 200a due to the malfunction of the rotor 210a may be reduced.

FIG. 1B is a diagram illustrating a first state of the apparatus for processing rotor movement information and the electronic device 200a, according to an embodiment.

Referring to FIG. 1B, a user of the electronic device 200a may control (F1) the rotor 210a with a first finger (finger 1) and touch (F2) at least one of the second to fourth surfaces 202 to 204 with a second finger (finger2).

In this case, the electronic device 200a and the processor 100 may operate in a first state and may produce electronic device operating information or display information based on the movement information of the rotor 210a.

FIG. 1C is a diagram illustrating a second state of the apparatus for processing rotor movement information and the electronic device 200a, according to an embodiment.

Referring to FIG. 1C, the user of the electronic device 200a may control the rotor 210a with the first finger (finger 1) and may have no touch on the second to fourth surfaces 202 to 204.

In this case, the electronic device 200a and the processor 100 may operate in a second state and may produce electronic device operating information or display information irrelevant to the movement information of the rotor 210a, as compared to when in the first state.

Further, the electronic device 200a and the processor 100 may select one of the first and second states in which to operate, depending on whether a touch is held on the second to fourth surfaces 202 to 204.

For example, the processor 100 and the electronic device 200a may receive touch information of a sensor 220a at a relatively short interval (e.g., every 1 sec or less) and may select one of the first and second states in which to operate, based on most recent touch information.

Referring to FIGS. 1A to 10, the electronic device 200a may further include a switch 215 configured to determine whether the switch 215 is in contact with the rotor 210a depending on the rotation axis translational motion of the rotor 210a. The processor 100 may receive rotation axis translational motion information based on the switch 215.

Accordingly, the processor 100 and the electronic device 200a may more clearly determine whether the rotor 210a has moved. Since the processor 100 and the electronic device 200a may select one of the first and second states in which to operate, in accordance with the more clearly determined movement, frequency of occurrence of unintended malfunction information (or display information) of the processor 100 and the electronic device 200a due to malfunctioning of the rotor 210a or unintended operation of the rotor 210a by the user may be further reduced.

Based on FIGS. 1A to 1C, a portion (e.g., the head 212) of the rotor 210a may protrude from the first surface 201 of the electronic device 200a, and the other portion (e.g., body 211) of the rotor 210a is inserted into the internal space 205 from the first surface 201 of the electronic device 200a. At least a portion of the body 211 may be a shaft.

Accordingly, the processor 100 and the electronic device 200a may receive a greater variety of movement information of the rotor 210a. The processor 100 and the electronic device 200a may process the information so that a correlation between the electronic operating information (or the display information) and the movement information of the rotor 210a varies in accordance with the touch information of the sensor 220a, thereby reducing a possibility of a malfunction to be induced due to the protrusion of a portion of the rotor 210a.

Based on FIGS. 1A to 10, the processor 100 and the electronic device 200a may produce electronic movement information (or display information) based on the rotation axis translational motion information of the rotor 210a.

The rotation axis translational motion information, out of the rotation angle information, rotation axis translational motion information and rotation axis vertical motion information of the rotor 210a, may have a highest correlation to the touch information of the sensor 220.

Accordingly, the processor 100 and the electronic device 200a may effectively reduce frequency of occurrence of unintended malfunction information (or display information) of the processor 100 and the electronic device 200a due to malfunctioning of the rotor 210a (or unintentional operation of the rotor 210a) by producing the electronic device operating information (or display information) based on the rotation axis translational motion information of the rotor 210a.

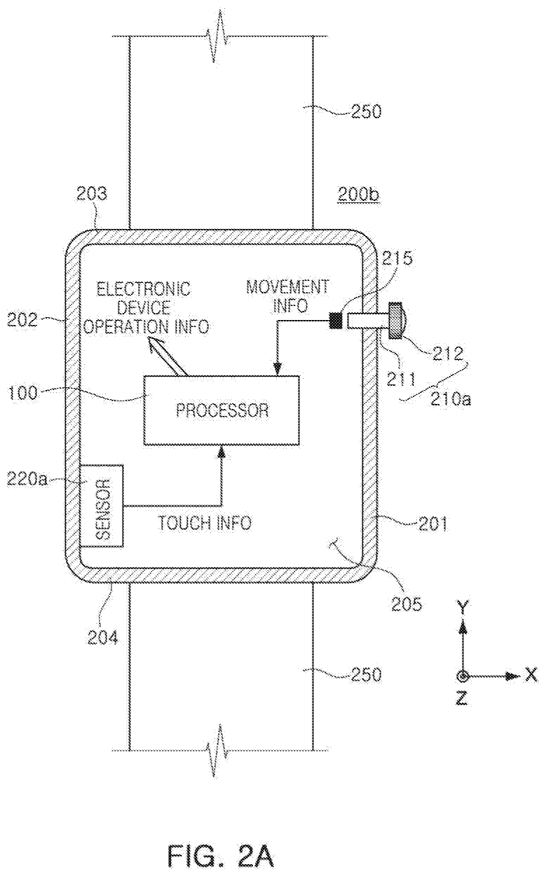

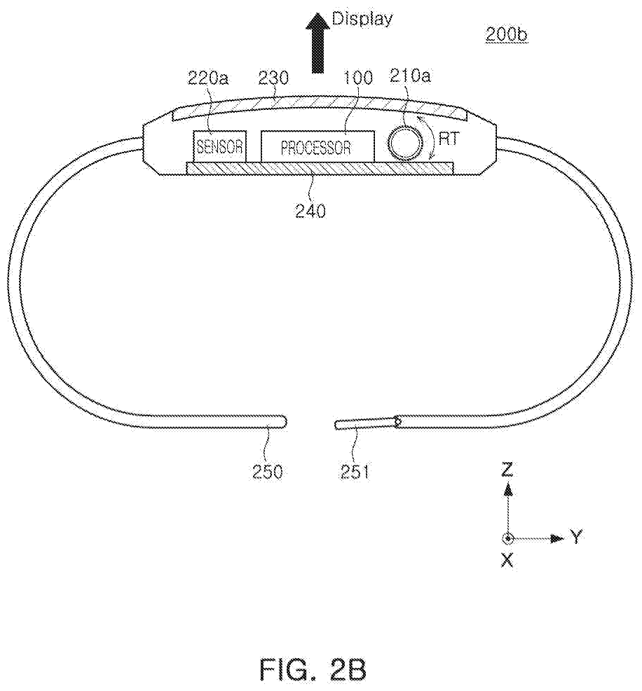

FIGS. 2A and 2B are diagrams illustrating a wearable structure of an apparatus for processing rotor movement information and an electronic device 200b, according to an embodiment.

Referring to FIGS. 2A and 2B, the electronic device 200b may be connected to at least one of first to fourth surfaces 201 to 204 of a main body, and may further include a strap 250 that is more flexible than the main body.

Accordingly, since the strap 250 may be worn on a body (or clothing) of a user of the electronic device 200b, the user can use the electronic device 200b more conveniently. For example, one end and another end of the strap 250 may be coupled to each other via a binding portion 251.

The processor 100 and the electronic device 200b may process the information so that a correlation between the electronic operating information (or display information) and the movement information of the rotor 210a varies in accordance with the touch information of the sensor 220a, thereby reducing frequency of occurrence of malfunction information due to an impact of the rotor 210a with the body (or clothing) of the user.

referring to FIG. 2B, the electronic device 200b may include a display member 230 and a board 240.

The display member 230 may output display information in a normal line (e.g., z direction) of the display member 230 different from a normal line (e.g., x direction and/or y direction) of the first to fourth surfaces 201 to 204 of the main body. The normal lines of the display member 230 and the main body of the electronic device 200b may be identical to each other.

Accordingly, the user may control the rotor 210a more conveniently. The processor 100 and the electronic device 200b may process the information so that a correlation between the electronic operating information and the movement information (or display information) of the rotor 210a varies in accordance with the touch information of the sensor 220a, thereby reducing frequency of occurrence of malfunction information due to an arrangement direction of the rotor 210a.

At least a portion of the display information output by the display member 230 may be based on the electronic device operating information produced by the processor 100. That is, the processor 100 may deliver the display information based on the electronic device operating information to the display member 230.

For example, the display member 230 may have a structure in which a plurality of display cells are arranged two-dimensionally and may receive a plurality of control signals based on the electronic device operating information from the processor 100 or an additional processor. One or more of the plurality of display cells may be configured to determine a color or determine whether to illuminate based on a plurality of control signals. For example, the display member 230 may further include a touchscreen panel and may be formed of a relatively flexible material, such as an organic light emitting device (OLED).

The board 240 may provide an arrangement space for the processor 100 and/or the sensor 220a, and may provide an information delivering path between the processor 100 and the display member 230. For example, the board 240 may be implemented as a printed circuit board (PCB).

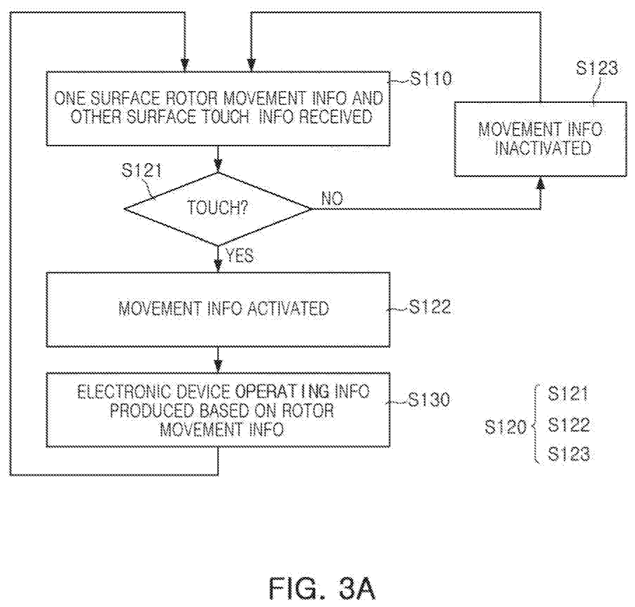

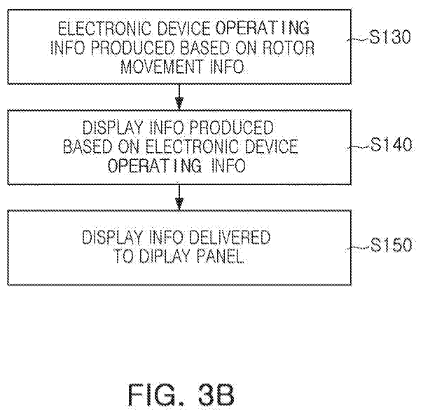

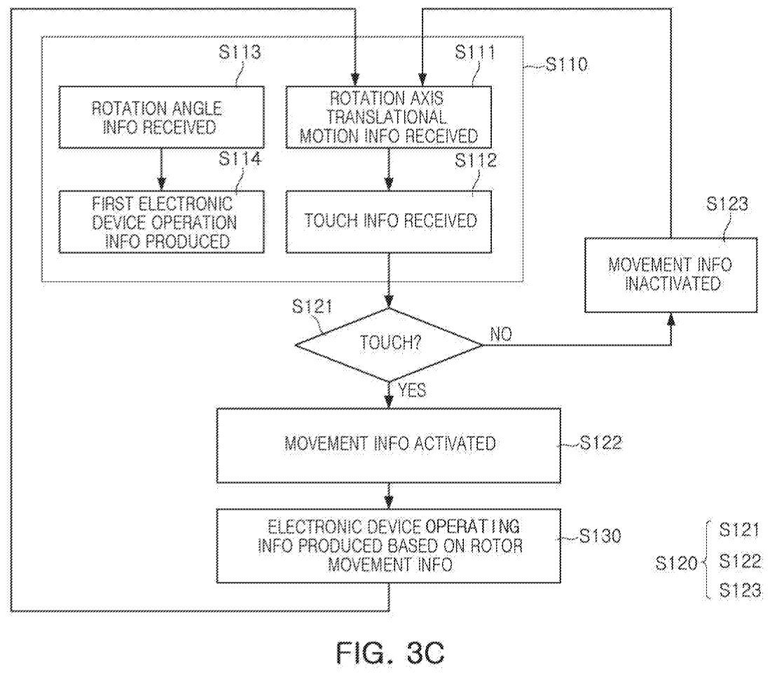

FIG. 3A is a flow chart of a method for processing movement information of a rotor (e.g., the rotor 210a), according to an embodiment.

Referring to FIG. 3A, the method for processing movement information of the rotor may include a receiving process S110, an activating process S120, and a producing process S130.

In the receiving process S110, a processor (e.g., the processor 100) or an electronic device (e.g., the electronic device 200a or 200b) may receive movement information of the rotor disposed on one surface of the electronic device (e.g., the first surface 201) and touch information of a sensor (e.g., the sensor 220a) sensing a touch on the other surface (e.g., one or more of the second to fourth surfaces 202 to 204) of the electronic device.

In the activating process S120, the processor or the electronic device may selectively activate the movement information depending on the touch information.

For example, in operation S121, the processor or the electronic device determines whether the touch information corresponds to a touch having occurred, or corresponds to a touch having not occurred. When the touch information corresponds to an occurrence of a touch, the movement information may be activated in operation S122. Alternatively, when the touch information corresponds to an absence of a touch, the movement information may be inactivated in operation S123.

In the producing process S130, the processor or the electronic device may produce the electronic device operating information based on the movement information of the rotor in accordance with the activation of the movement information.

Accordingly, frequency of occurrence of unintended electronic device operating information (or display information) of the processor and the electronic device due to malfunctioning of the rotor may be effectively reduced.

FIG. 3B is a flow chart illustrating a display linkage process of a method for processing movement information of a rotor, according to an embodiment.

Based on FIG. 3B, the method for processing movement information of the rotor, according to an embodiment, may further include a displaying process S140 and a display information delivering process S150.

Referring to FIG. 3B, the processor or the electronic device may produce display information based on the electronic device operating information in the displaying process S140.

In the information delivering process, the processor or the electronic device may deliver the display information to the display member (e.g., the display member 230), which outputs the display information on a display surface having a normal line different from a normal line of one surface and the other surface of the electronic device.

FIG. 3C is a flow chart illustrating a selective application process of rotor motion information of a method for processing movement information of a rotor according to an example embodiment.

Referring to FIG. 3C, the method for processing movement information of a rotor, according to an embodiment, may include the receiving process S110 described with respect to FIG. 3A. The receiving process 110 may include receiving rotation axis translational motion information in operation S111, receiving touch information in operation S112, receiving rotation angle information in operation S113, and producing first electronic device operating information in operation S114.

That is, as illustrated in FIG. 3C, the processor or the electronic device may process rotation axis translational motion information in accordance with activation of the movement information and may process rotation angle information relatively irrelevantly to the activation of the movement information.

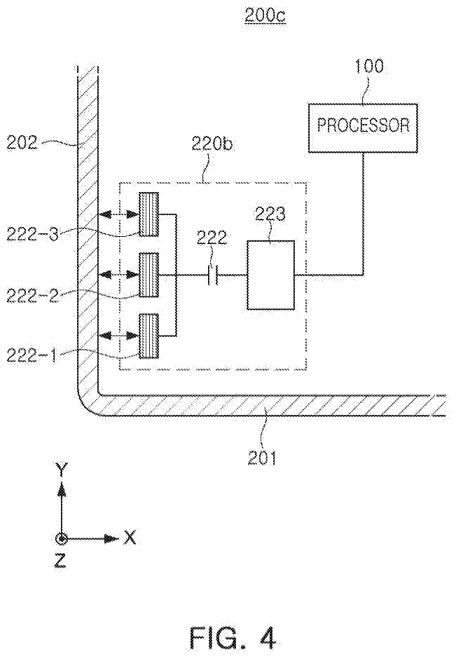

FIG. 4 is a diagram illustrating a sensor 220b of an apparatus for processing rotor movement information and an electronic device 200c, according to an embodiment.

Referring to FIG. 4, the processor 100 and the electronic device 200c may include the sensor 220b. For example, the sensor 220b may include a plurality of inductors 222-1, 222-2, and 222-3, a capacitor 222, and a touch information processor 223.

For example, when a user's finger touches the second surface 202 of the main body, a distance between the second surface 202 and at least one of the plurality of inductors 222-1, 222-2, and 222-3 may be reduced.

When the distance between the second surface 202 and the at least one of the plurality of inductors 222-1, 222-2, and 222-3 is reduced, inductance of the plurality of the inductors 222-1, 222-2, and 222-3 may be increased by an increased electromagnetic coupling coefficient for the second surface 202.

The touch information processor 223 may detect whether a user's finger touches the second surface 202 by detecting a change in a resonance frequency formed by the plurality of inductors 222-1, 222-2, and 222-3, and the capacitor 222.

For example, the touch information processor 223 may output a sensing current to the plurality of the inductors 222-1, 222-2, and 222-3, and characteristics (e.g., maximum current) of the sensing current may be determined by the resonance frequency of the sensor 220b. The touch information processor 223 may produce touch information based on the characteristics of the sensing current.

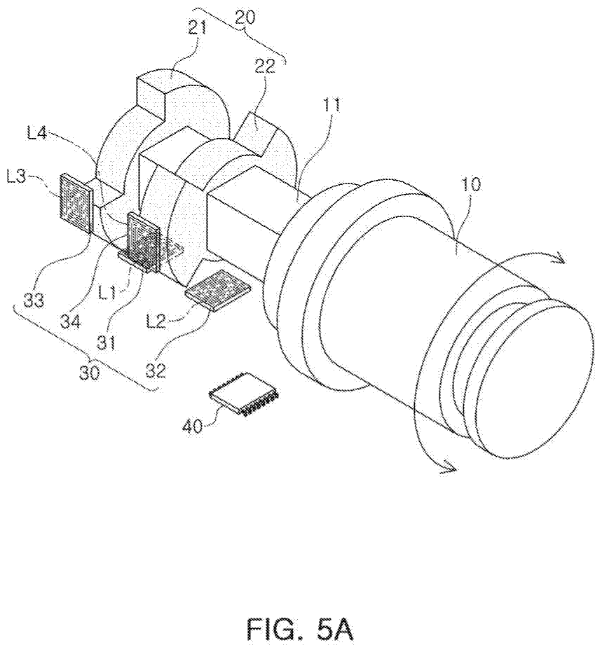

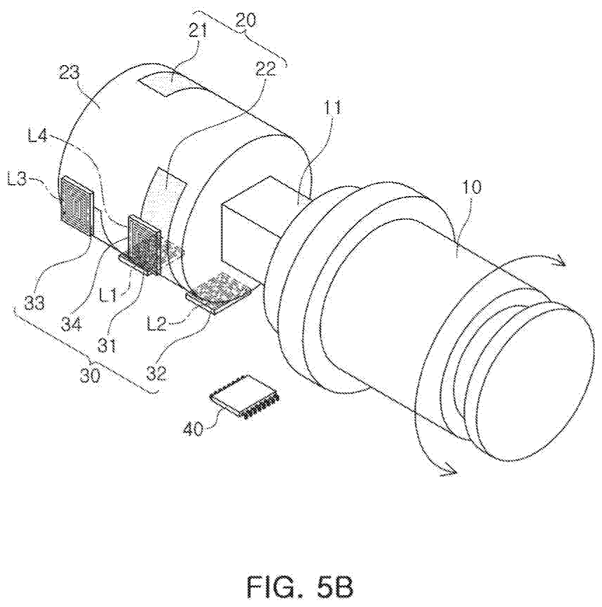

FIGS. 5A and 5B are diagrams illustrating detailed structures of rotors that may be included in an apparatus for processing rotor movement information and an electronic device, according to an embodiment.

Based on FIGS. 5A and 5B, a rotor may include a wheel 10, a rotation axis 11 and a detected portion 20. An apparatus for processing rotor movement information and an electronic device, according to an embodiment, may include a rotation sensor 30 and a rotation information calculator 40.

The detected portion 20 may be connected to the wheel 10 via the rotation axis 11. The wheel is employed in an electronic device and may be understood as a rotor rotated clockwise or counterclockwise by a user. The detected portion 20 may be rotated together with the wheel 10, clockwise or counterclockwise.

The detected portion 20 may include a first pattern portion 21 and a second pattern portion 22. The first pattern portion 21 and the second pattern portion 22 are formed to have an identical shape, and are spaced apart by a predetermined distance in a direction in which the rotation axis 11 extends. The first pattern portion 21 and the second pattern portion 22 are coupled to the rotation axis, and may rotate in the same direction and at the same speed when the rotor rotates.

The first pattern portion 21 and the second pattern portion 22 may include a plurality of patterns having an identical shape. The first pattern portion 21 may include a plurality of first patterns, and the second pattern portion 22 may include a plurality of second patterns.

In FIG. 5A, a protruding portion of the first pattern portion 21 and the second pattern portion 22 corresponds to a pattern. For example, a plurality of the first patterns of the first pattern portion 21 and a plurality of the second patterns of the second pattern portion 22 may be manufactured by processing a disk-shaped metal and a magnetic substance to form teeth. Accordingly, the plurality of first patterns of the first pattern portion 21 and the plurality of second patterns of the second pattern portion 22 may be formed of either one of a metal and a magnetic substance.

The plurality of first patterns of the first pattern portion 21 extend in a rotation direction, and the plurality of second patterns of the second pattern portion 22 extends in a rotation direction. A length of the first pattern extending in the rotation direction may be defined as a size of the first pattern, and a length of the second pattern extending in the rotation direction may be defined as a size of the second pattern.

The plurality of first patterns of first pattern portion 21 are spaced apart by a predetermined distance in the rotation direction, and the plurality of second patterns of the second pattern portion 22 are spaced apart by a predetermined distance in the rotation direction. For example, the space between the plurality of first patterns of the first pattern portion 21 may be identical to the size of each first pattern, and the space between the plurality of second patterns of the second pattern portion 22 may be identical to the size of each second pattern.

The plurality of first patterns of the first pattern portion 21 and the plurality of second patterns of the second pattern portion 22 may be disposed to have a predetermined angle difference. For example, the plurality of first patterns of the first pattern portion 21 and the plurality of second patterns of the second pattern portion 22 may be disposed to have an angle difference corresponding to a half of the size of each first pattern and half of the size of each second pattern, respectively.

Based on an example in which the first pattern portion 21 includes two first patterns having a size of 90° and the second pattern portion 22 includes two second patterns having a size of 90°, the two first patterns and the two second patterns may be disposed to have an angle difference of 45°. In this regard, the two first patterns and the two second patterns may partially overlap in a direction in which the rotation axis 11 extends.

The rotation sensor 30 may include a plurality of sensors. For example, the sensor 30 may include a first rotation sensor 31, a second rotation sensor 32, a third rotation sensor 33 and a fourth rotation sensor 34. The first and second rotation sensors 31 and 32 are, for example, disposed on a first plane in the direction in which the rotation axis 11 extends. For example, the first rotation sensor 31 is disposed to oppose the first pattern portion 21, and the second sensor 32 is disposed to oppose the second pattern portion 22. Further, the third and fourth rotation sensors 33 and 34 may be disposed on a second plane in the direction in which the rotation axis 11 extends. The third rotation sensor 33 may be disposed to oppose the first pattern portion 21, and the fourth sensor 34 is disposed to oppose the second pattern portion 22. The first and second planes may be disposed to have a predetermined angle therebetween.

Due to rotations of the first pattern portion 21 and the second pattern portion 22, an area of the first and third sensors 31 and 33 overlapping with the first pattern of the first pattern portion 21 changes, and an area of the second and fourth sensors 32 and 34 overlapping with the second pattern of the second pattern portion 22 changes. The first and third sensors 31 and 33 may detect a change in the overlapping area with the first pattern portion 21, and the second and fourth sensors 32 and 34 may detect a change in the overlapping area with the second pattern portion 22.

The first to fourth rotation sensors 31 to 34 may have a predetermined size. In this case, the sizes of the first to fourth rotation sensors 31 to 34 may be understood as lengths corresponding to the direction in which the rotor rotates. For example, the sizes of the first to fourth rotation sensors 31 to 34 may correspond to a half of the size of the first pattern of the first pattern portion 21 and a half of the size of the second pattern of the second pattern portion 22.

The first and third rotation sensors 31 and 33 may be disposed to have an angle difference equivalent to the size of the first pattern, and the second and fourth rotation sensors 32 and 34 may be disposed to have an angle difference equivalent to the size of the second pattern. The first sensing value output from the first rotation sensor 31 and the third sensing value output from the third rotation sensor 33 may be 180 degrees out of phase with each other due, to the arrangement of the first and third rotation sensors 31 and 33 to have the angle difference equivalent to the size of the first pattern. Further, the second sensing value output from the second rotation sensor 32 and the fourth sensing value output from the fourth rotation sensor 34 may be 180 degrees out of phase with each other, due to the arrangement of the second and fourth rotation sensors 32 and 34 to have the angle difference equivalent to the size of the second pattern.

The first to fourth rotation sensors 31 to 34 may include sensing coils L1 to L4, respectively. The sensing coils L1 to L4 may be formed by forming a circuit pattern on a board. According to example embodiments, the sensing coils L1 to L4 may be formed of either one of a wound inductor coil and a solenoid coil. The first to fourth rotation sensors 31 to 34 including the sensing coils L1 to L4 may detect a rotation angle and a rotation direction of the rotor, in accordance with inductance varying depending on the overlapping areas with the first pattern portion 21 and the second pattern portion 22.

The rotation information calculator 40 may be implemented as an integrated circuit and may be electrically connected to the first to fourth rotation sensors 31 to 34. The rotation information calculator 40 may calculate rotation information including the rotation angle and the rotation direction of the rotor in accordance with the changes in inductance of the first to fourth rotation sensors 31 to 34.

Referring to FIG. 5B, an apparatus for processing rotor movement information and an electronic device, according to an embodiment, may further include a support member 23 connected to the rotation axis 11. Since the rotor of FIG. 5B is similar to the rotor of FIG. 5A, repeated descriptions will be omitted, and differences therebetween will be described. The support member 23 is connected to the rotation axis 11 and may rotate clockwise or counterclockwise with respect to the rotation axis 11 according to the rotation of the wheel 10. For example, the support member 23 may be formed to have a cylindrical shape. The detected portion 20 may be disposed in the support member 23. The detected portion 20 may include the first pattern portion 21 and the second pattern portion 22 disposed on side surfaces of the support member 23.

The first pattern portion 21 may include the plurality of first patterns extending in the rotation direction in a first height region of the cylindrical-shaped support member 23, and the second pattern portion 22 may include the plurality of second patterns extending in the rotation direction in a second height region of the cylindrical-shaped support member 23. The plurality of first patterns of the first pattern portion 21 and the plurality of second patterns of the second pattern portion 22 may be formed of either one of a metal or a magnetic substance.

The support member 23 may be formed of a non-metal substance, such as a plastic, while the first pattern portion 21 and the second pattern portion 22 may be formed of a metal. The support member 23 may be manufactured through a process of injection molding a plastic, while the first pattern portion 21 and the second pattern portion 22 may be formed through a plating process.

When the first pattern portion 21 and the second pattern portion 22 are disposed on the side surfaces of the support member 23, a groove is formed on the side surfaces of the support member 23 such that the first pattern portion 21 and the second pattern portion 22 are disposed in the groove. For example, a step may be formed in the support member 23 due to the groove extending in the rotation direction. The first pattern portion 21 and the second pattern portion 22, when disposed on the side surfaces of the support member 23, may be externally exposed. For example, thicknesses of the first pattern portion 21 and the second pattern portion 22 may be identical to a thickness of the groove.

The apparatus for processing rotor movement information and an electronic device according to the embodiment of FIG. 5B may be advantageous in mass production and cost reduction by implementing manufacturing of a thin pattern using a method having excellent mass productivity such as an injection molding process and a plating process.

According to embodiments disclosed herein, frequency of occurrence of unintended malfunction information (or display information) of an electronic device and a processor due to a malfunction or an unintended user operation of a rotor of the electronic device may be effectively reduced.

The processor 100, the touch information processor 223, and the rotation information calculator 40 in FIGS. 1A to 5B that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1A to 5B that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. An apparatus for processing rotor movement information, comprising:
a processor configured to:
receive movement information of a rotor disposed on one surface of an electronic device and having a rotation axis formed in a direction of the electronic device;
receive touch information of a sensor configured to sense a touch on another surface of the electronic device; and
produce operating information of the electronic device based on the movement information of the rotor,
wherein the operating information of the electronic device has variable correlation of the operating information to the movement information, in accordance with the touch information, and
wherein the sensor comprises a plurality of inductors having an inductance that changes in response to a change in a distance between the other surface of the electronic device and one or more of the plurality of inductors, and the sensor is configured to generate the touch information based on characteristics of a sensing current applied to the plurality of inductors.

2. The apparatus of claim 1, wherein the electronic device is configured to output display information on a display surface, and
wherein the one surface and the other surface of the electronic device have a normal line different from a normal line of the display surface.

3. The apparatus of claim 2, wherein a portion of the display information is based on the operating information.

4. The apparatus of claim 3, wherein the processor is further configured to deliver the portion of the display information to a display member of the electronic device.

5. The apparatus of claim 1, wherein the movement information includes rotation angle information of the rotor and rotation axis translational motion information of the rotor, and
wherein the processor is further configured to produce the operating information based on the rotation axis translational motion information.

6. The apparatus of claim 5, wherein the processor is further configured to receive the rotation axis translational motion information based on a switch configured to determine whether the switch contacts the rotor depending on rotation axis translational motion of the rotor.

7. The apparatus of claim 5, wherein the processor is further configured to receive the rotation angle information based on a sensing coil configured to vary inductance in accordance with a rotation angle of the rotor.

8. (canceled)

9. The apparatus of claim 1, wherein the processor is further configured to produce the operating information to vary correlation of the operating information to the movement information depending on whether the touch is held on the other surface of the electronic device.

10. A method for processing rotor movement information, comprising:
receiving movement information of a rotor disposed on one surface of an electronic device and having a rotation axis formed in a direction of the electronic device, and touch information of a sensor configured to sense a touch on another surface of the electronic device;
selectively activating the movement information depending on the touch information; and
producing operating information of the electronic device based on the movement information, in accordance with the selectively activating of the movement information,
wherein the sensor comprises a plurality of inductors having an inductance that changes in response to a change in a distance between the other surface of the electronic device and one or more of the plurality of inductors, and the sensor is configured to generate the touch information based on characteristics of a sensing current applied to the plurality of inductors.

11. The method of claim 10, further comprising producing display information based on the operating information.

12. The method of claim 11, further comprising delivering the display information to a display member, wherein the display member is configured to output the display information on a display surface having a normal line different from a normal line of the one surface and the other surface of the electronic device.

13. The apparatus of claim 10, wherein the movement information includes rotation angle information of the rotor and rotation axis translational motion information of the rotor, and
wherein the producing of the electronic movement information comprises producing the operating information based on the rotation axis translational motion information while the movement information is activated.

14. An electronic device, comprising:
a main body;
a rotor disposed on one surface of the main body and having a rotation axis formed in a direction of the electronic device; and
a sensor configured to sense a touch on another surface of the main body,
wherein the main body is configured to output the display information on a display surface based on movement information of the rotor, such that correlation of the display information to the movement information varies depending on whether a touch is sensed on the other surface of the main body, and
wherein the sensor comprises a plurality of inductors having an inductance that changes in response to a change in a distance between the other surface of the main body and one or more of the plurality of inductors, and the sensor is configured to generate the touch information based on characteristics of a sensing current applied to the plurality of inductors.

15. The electronic device of claim 14, wherein the main body is configured to output first display information, among the display information, based on a rotation angle of the rotor and second display information, among the display information, based on rotation axis translational motion of the rotor.

16. The apparatus of claim 14, wherein one portion of the rotor protrudes from the one surface of the electronic device, and another portion of the rotor is inserted inward from the one surface of the electronic device.

17. The apparatus of claim 14, wherein the main body comprises a switch configured to determine whether the switch contacts the rotor in accordance with rotation axis translational motion of the rotor.

18. The apparatus of claim 14, further comprising a strap connected to the main body, wherein the strap is more flexible than the main body.

19. The apparatus of claim 14, wherein the main body is further configured to output the display information based on the movement information of the rotor, such that correlation of the display information to the movement information varies depending on whether the touch is held on the other surface of the main body.
